(19) United States
(12) Patent Application Publication
(10) Pub. No.: US 2005/0173724 A1
(43) Pub. Date: Aug. 11, 2005

(54) Group III-nitride based LED having a transparent current spreading layer

(76) Inventor: Heng Liu, Sunnyvale, CA (US)

Correspondence Address: MACPHERSON KWOK CHEN & HEID LLP, 1762 TECHNOLOGY DRIVE, SUITE 226, SAN JOSE, CA, 95110, US

(21) Appl. No.: 10/777,878

(22) Filed: Feb. 11, 2004

(51) Int. Cl. H01L 33/00; H01L 21/00

(52) U.S. Cl. 257/103; 438/22

(57) ABSTRACT

A light emitting device has an n-type layer and a p-type layer, which cooperate with one another to form a light generating region. At least one n+ layer is formed upon either the n-type layer or the p-type layer. At least one current spreading layer is formed upon the n+ layer.

### FIELD OF THE INVENTION

The present invention relates generally to the fabrication of light emitting diodes (LEDs). The present invention relates more particularly to a group III-nitride based LED having a transparent current spreading layer.

### BACKGROUND OF THE INVENTION

Light emitting diodes (LEDs) for use in a wide variety of different applications are well known. LEDs have been used as indicators, such as on the control panels of consumer electronic devices, for many years. LEDs are presently finding increasing use in other applications as the brightness thereof continues to increase and the cost thereof continues to decrease.

More particularly, group III-nitride based LEDs are finding rapidly increasing use in numerous existing and emerging applications. This popularity of LEDs is at least in part due to the continuous breakthroughs in material and device technology which have occurred over the past few years. Group III-nitride semiconductor materials include BN, GaN, AlN, InN, and their alloys. As used herein, the term AlInGaN is defined to represent group III-nitride materials generally. The lumen efficacy of white LEDs utilizing phosphors for down conversion, such as InGaN blue LEDs, has now surpassed traditional light sources such as tungsten lamps, high pressure gas discharge lamps, and even compact fluorescent lamps.

Because of their low power consumption, long lifetime and high reliability LEDs are desirable for use in such applications as traffic lights, outdoor video signs, automotive lights, and LCD backlights, as well as in many other applications. Nevertheless, the cost of making LEDs is much higher than the cost of making traditional light sources, even taking into account the advantages of increased lifetime and reduced power consumption which are provided by LEDs.

To date, cost is the primary obstacle that hinders the explosive use of LEDs in general illumination. However, it is important to appreciate that attention needs to be paid to efficiency improvement as well as lower manufacturing cost. As such, although contemporary LEDs have proven generally suitable for their intended purposes, contemporary LEDs continue to suffer from inherent deficiencies that tend to detract from their overall effectiveness and desirability in the marketplace. This is substantially due to their undesirably high cost and low efficiency.

According to the contemporary fabrication of AlInGaN based LEDs, multiple layers are epitaxially deposited on a substrate. Popular substrates for AlInGaN LEDs include sapphire, SiC, and Si, among others. The LED structure usually includes an active region for light generation, upper and lower confinement layers, as well as contact layers to facilitate ohmic electrode connections to an external power source. The upper and lower confinement layers are doped so as to form different semiconductor types, i.e., n and p-types, and thus define a diode structure with the active region being sandwiched in between.

Referring now to FIG. 1, a typical contemporary AlInGaN based LED structure is shown. This device comprises a p-type AlInGaN layer 11 and an n-type AlInGaN layer 12 which cooperate to define a light generating region 13. The n-type AlInGaN 12 is formed upon a substrate 14. P-electrode 15 facilitates electrical connection to the p-type AlInGaN 11 layer and n-electrode 16 similarly facilitates electrical connection to the n-type AlInGaN layer 12.

Due to the inherent limitations of the epitaxial process that produce this contemporary type of structure, the p-type layers are usually deposited after the active layers and n-layers. Since the p-type AlInGaN material exhibits poor conductivity and in order to spread current evenly in the cross section of the LED before going though the device, a layer of high conductivity material can be deposited on the p-layer to enhance current spreading.

It is important, however, that this current spreading layer needs to make good contact with the p-layer to avoid an excessive voltage drop across the interface. It is also important this current spreading layer needs to be as transparent as possible to avoid undesirable light absorption for light propagating in the upward direction.

Referring now to FIG. 2, a contemporary LED having a semi-transparent current spreading layer 20 is shown. A thin semi-transparent metal current spreading layer 20 is deposited across the top surface of the p-layer 11 of the LED. The material of the metal current spreading layer 20 can be chosen so as to make good ohmic contact to the p-layer 11. One example of such a metal is Ni/Au.

Event though it is very thin, the metal current spreading layer 20 still undesirably absorbs a significant amount of light. To overcome this shortcoming, a GaN based tunneling contact layer can be employed.

Referring now to FIG. 3, according to contemporary practice a heavily doped p⁺-GaN layer 32 can be added on top of the p-layer 11 and thus be used as a tunneling contact to an ITO (Indium Tin Oxide) current spreading layer 31. When the heavily doped p⁺-GaN layer 32 is made very thin (less than a few hundred angstroms), current injected from the ITO current spreading layer 31 can go through the p⁺-GaN layer 32 by the tunneling effect.

Since ITO and p⁺-GaN do not substantially absorb the light generated by the active region, the light efficiency is much improved. However, the ITO does not make very good electrical contact to p⁺-GaN and a device made this way usually requires an undesirably high turn-on voltage. Heat generated due to excessive voltage drop across the interface between ITO and p⁺-GaN can often degrade device performance.

Referring to FIG. 4, a different approach is to use a reverse biased tunnel diode on top of the p-layer 11. A heavily doped n⁺-GaN layer 41 is deposited on top of the p-layer (p-GaN) 11 to form the tunnel diode. A less heavily doped and thicker n-GaN layer 42 is formed on top of the n⁺-GaN layer 41 and is used for spreading the current.

When the doping concentrations of the p-layer and n-layer that form the tunnel diode are made very high (greater than 10¹⁹ cm⁻³), then the voltage drop across the tunnel diode can be as low as a fraction of a volt. The forward voltage of the LED can therefore be kept low and the tunnel diode design does not result in excessive power consumption.

Since p-GaN, n-GaN and n⁺-GaN are transparent to the light generated in the active region, such prior art devices have good light output efficiency. However, there are a few issues with the design shown in FIG. 4. Even though n-type GaN exhibits much higher conductivity than p-type GaN, it is still not a very good conductor for current spreading in typical LED chip designs. Compared to many other types of semiconductor materials, such as GaAs, InP, Si, etc, the resistivity of GaN is about two orders of magnitude higher. At about 1 micron thickness, the sheet resistivity of the n-GaN or n⁺-GaN is on the order of 200 ohm/sq. For a good current spreading layer in a typical LED such as GaAs or InP based LEDs, the sheet resistivity is usually in the order of 2 ohm/sq or less.

This becomes a more significant issue when designing a large area device, where uniform current spreading is more difficult to achieve. One can grow, of course, a thicker n-GaN current spreading layer to increase the conductivity. This is, however, difficult to achieve in practice. The reason is that InGaN is normally used as the active layer in a typical group III-Nitride based LED due to its desirable emitting wavelength in the visible spectrum. The material is, however, susceptible to degradation at high temperatures. Therefore, the layers in an InGaN based LED structure after the InGaN is deposited are normally grown at their lowest possible temperatures to preserve the quality of InGaN. By the same token, these layers are also grown as thin as possible. Therefore, the use of a thick n-GaN on top of the p-GaN layer for current spreading is not practical.

GaN and AlGaN doped with Mg are typical p-type materials used as cladding and contacting layers on top of the InGaN active layer. GaN and AlGaN prefer growing at high temperatures, normally greater than 1000° C. However, in actual practice, they are often grown at temperatures lower than 1000° C. A most popular temperature range being used is about 850° C. to 950° C. At such low temperatures, the Mg doped GaN and AlGaN layers are grown to only a few tenths of a micron to maintain their material quality. Likewise, when trying to grow thick n-GaN or n⁺-GaN on top of the p-layers for current spreading at such low temperatures, the material quality will suffer. Normally pits and rough surface morphology are seen on wafers grown this way.

As such, although the prior art has recognized, to a limited extent, the problems of lumen efficiency and cost, the proposed solutions have, to date, been ineffective in providing a satisfactory remedy. Therefore, it is desirable to provide an LED and a method for making the same wherein enhanced brightness is provided and/or lower costs of production are achieved.

### BRIEF SUMMARY OF THE INVENTION

While the apparatus and method has or will be described for the sake of grammatical fluidity with functional explanations, it is to be expressly understood that the claims, unless expressly formulated under 35 USC 112, are not to be construed as necessarily limited in any way by the construction of “means” or “steps” limitations, but are to be accorded the full scope of the meaning and equivalents of the definition provided by the claims under the judicial doctrine of equivalents, and in the case where the claims are expressly formulated under 35 USC 112 are to be accorded full statutory equivalents under 35 USC 112.

The present invention specifically addresses and alleviates the above mentioned deficiencies associated with the prior art. More particularly, according to one aspect the present invention comprises a light emitting device comprising two differently doped semiconductor materials which cooperate to define a light generating region. At least one n+ layer is formed upon at least one of the two semiconductor materials and a current spreading layer is formed upon the n+ layer.

According to another aspect, the present invention comprises a light emitting device comprising an n-type layer and a p-type layer cooperating with the n-type layer to form a light generating region. At least one n+ layer is formed upon the n-type layer and/or the p-type layer and at least one current spreading layer is formed upon the n+ layer.

Typically, the light emitting device further comprises a substrate upon which the n-type layer and/or the p-type layer are formed. Typically, only one of the n-type layer and the p-type layers is formed upon the substrate. For example, the n-type layer may be formed upon the substrate and the n+ layer is then formed upon the p-type layer.

Alternatively, the p-type layer may be formed upon the substrate and the n+ layer is then formed upon the n-type layer.

The n-type layer and the p-type layer preferably comprise AlInGaN. However, as those skilled in the art will appreciate, various other semiconductor materials are likewise suitable.

The n+ layer preferably comprises GaN. However, as those skilled in the art will appreciate, various other semiconductor material are likewise suitable.

The current spreading layer preferably comprises a conductive oxide layer. For example, the current spreading layer may comprise an indium tin oxide layer. Examples of suitable indium oxide layers include InO_{X}, Indium Tin Oxide, and SnO_{X}.

Alternatively, the current spreading layer may comprise a zinc oxide layer. Examples of suitable zinc oxide layers include ZnO, ZnGaO, and ZnAlO.

The current spreading layer and the n+ layer are substantially transparent to at least one wavelength of visible light. Thus, the current spreading layer and the n+ layer allow a substantial amount of light from the light generating region to pass therethrough.

The sheet resistivity of the current spreading layer is preferably less than approximately 200 ohms/sq and is preferably between approximately 10 ohms/sq and approximately 200 ohm/sq.

The thickness of the n+ layer is preferably less than approximately 100 angstroms.

The doping concentration of the n+ is preferably greater than 10¹⁹ cm⁻³.

The conductive oxide layer is preferably in ohmic contact with the n-layer.

Preferably, the n+ layer cooperates with at least one of the n-type layer and the p-type layer to define a tunneling diode.

Preferably, the thickness of the oxide layer is an integer number of T, where T is 0.25λnm/n_{oxide}, λ is the emitting wavelength of the light generated from the light emitting device, and n_{oxide} is the refractive index of the oxide material.

According to another aspect, the present invention comprises a method for forming a light emitting device, wherein the method comprises forming a light generating region from two differently doped semiconductor materials, forming at least one n+ layer upon at least one of the two semiconductor materials, and forming a current spreading layer upon the n+ layer.

According to another aspect, the present invention comprises a method for forming a light emitting device, wherein the method comprises forming an n-type layer and a p-type layer in a manner such that they cooperate with one another to define a light generating region, forming at least one n+ layer upon at least one of the n-type layer and the p-type layer, and forming at least one current spreading layer upon the n+ layer.

The n+ layer is preferably formed at a temperature of less than approximately 900° C., preferably between approximately 700° C. and approximately 900° C.

These, as well as other advantages of the present invention, will be more apparent from the following description and drawings. It is understood that changes in the specific structure shown and described may be made within the scope of the claims, without departing from the spirit of the invention.

### BRIEF DESCRIPTION OF THE DRAWINGS

The invention and its various embodiments can now be better understood by turning to the following detailed description of the preferred embodiments which are presented as illustrated examples of the invention defined in the claims. It is expressly understood that the invention as defined by the claims may be broader than the illustrated embodiments described below.

FIG. 1 is a semi-schematic cross-sectional side view of a typical prior art AlInGaN LED;

FIG. 2 is a semi-schematic cross-sectional side view of a prior art AlInGaN LED showing a semi-transparent current spreading layer;

FIG. 3 is a semi-schematic cross-sectional side view of a prior art AlInGaN LED having a p⁺-GaN tunneling contact layer and an ITO transparent conductive current spreading layer;

FIG. 4 is a semi-schematic cross-sectional side view of a prior art AlInGaN LED having an n⁺-GaN reverse biased tunneling contact layer and an n-GaN transparent current spreading layer;

FIG. 5 is a semi-schematic cross-sectional side view of one exemplary embodiment of the present invention utilizing an n⁺-GaN contact layer on an LED structure with a p-type AlInGaN top layer, wherein an ITO transparent conductive oxide layer in ohmic contact with the n⁺-GaN is used as a current spreading layer; and

FIG. 6, is a semi-schematic cross-sectional side view of another exemplary embodiment of present invention utilizing an n⁺-GaN contact layer on an LED structure with an n-type AlInGaN top layer, wherein an ITO transparent conductive oxide layer in ohmic contact with the n⁺-GaN is used as a current spreading layer.

### DETAILED DESCRIPTION OF THE PREFERRED EMBODIMENTS

Many alterations and modifications may be made by those having ordinary skill in the art without departing from the spirit and scope of the invention. Therefore, it must be understood that the illustrated embodiment has been set forth only for the purposes of example and that it should not be taken as limiting the invention as defined by the following claims. For example, notwithstanding the fact that the elements of a claim are set forth below in a certain combination, it must be expressly understood that the invention includes other combinations of fewer, more or different elements, which are disclosed herein even when not initially claimed in such combinations.

The words used in this specification to describe the invention and its various embodiments are to be understood not only in the sense of their commonly defined meanings, but to include by special definition in this specification structure, material or acts beyond the scope of the commonly defined meanings. Thus if an element can be understood in the context of this specification as including more than one meaning, then its use in a claim must be understood as being generic to all possible meanings supported by the specification and by the word itself.

The definitions of the words or elements of the following claims therefore include not only the combination of elements which are literally set forth, but all equivalent structure, material or acts for performing substantially the same function in substantially the same way to obtain substantially the same result. In this sense it is therefore contemplated that an equivalent substitution of two or more elements may be made for any one of the elements in the claims below or that a single element may be substituted for two or more elements in a claim. Although elements may be described above as acting in certain combinations and even initially claimed as such, it is to be expressly understood that one or more elements from a claimed combination can in some cases be excised from the combination and that the claimed combination may be directed to a subcombination or variation of a subcombination.

Insubstantial changes from the claimed subject matter as viewed by a person with ordinary skill in the art, now known or later devised, are expressly contemplated as being equivalently within the scope of the claims. Therefore, obvious substitutions now or later known to one with ordinary skill in the art are defined to be within the scope of the defined elements.

The claims are thus to be understood to include what is specifically illustrated and described above, what is conceptionally equivalent, what can be obviously substituted and also what essentially incorporates the essential idea of the invention.

Thus, the detailed description set forth below in connection with the appended drawings is intended as a description of the presently preferred embodiments of the invention and is not intended to represent the only forms in which the present invention may be constructed or utilized. The description sets forth the functions and the sequence of steps for constructing and operating the invention in connection with the illustrated embodiments. It is to be understood, however, that the same or equivalent functions may be accomplished by different embodiments that are also intended to be encompassed within the spirit of the invention.

The present invention relates to light emitting diode (LED) devices and methods for producing and operating the same. More particularly, the present invention relates to a Group III-Nitride LED having improved design and output characteristics. The LED typically emits light from ultraviolet to yellow and can be used for LED signs, backlight and various lighting applications.

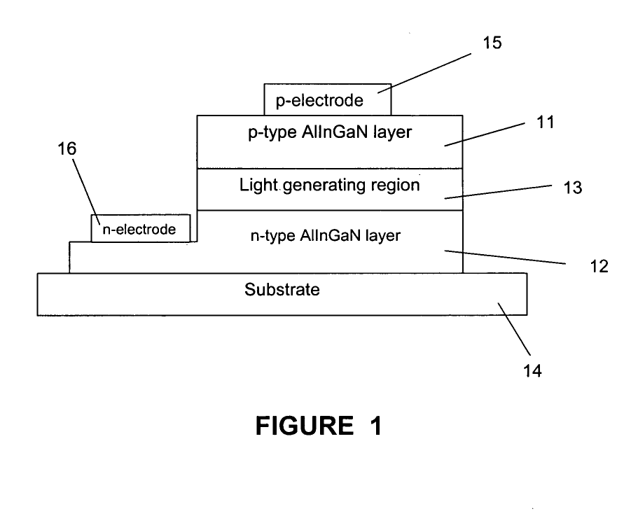

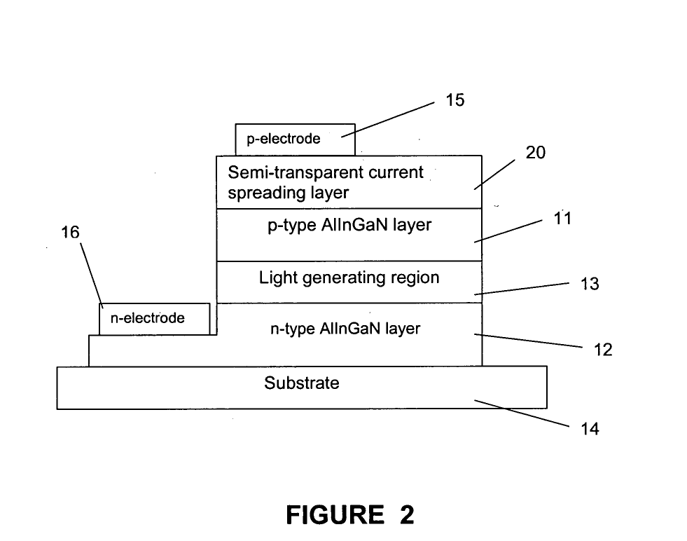

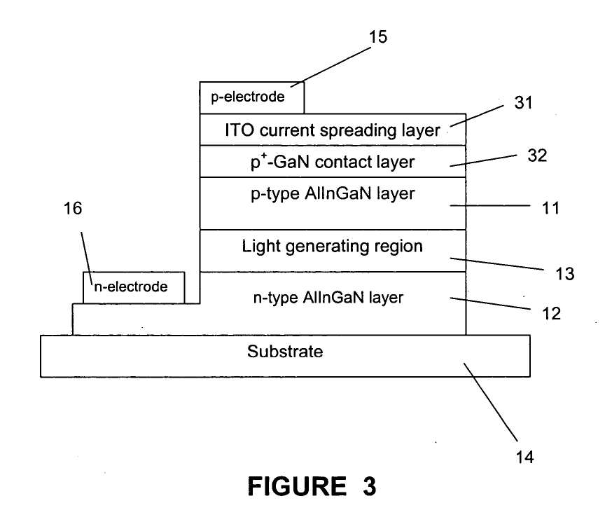

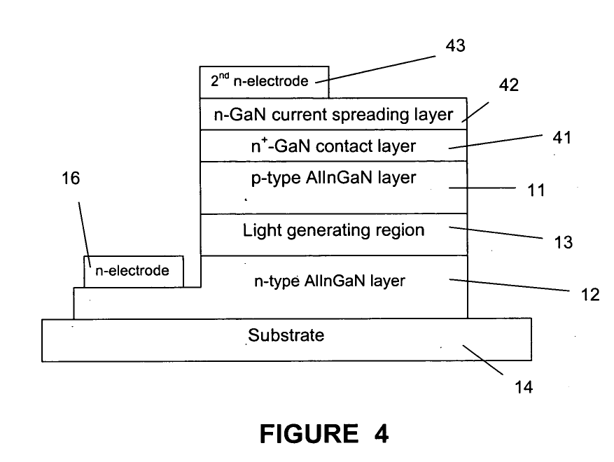

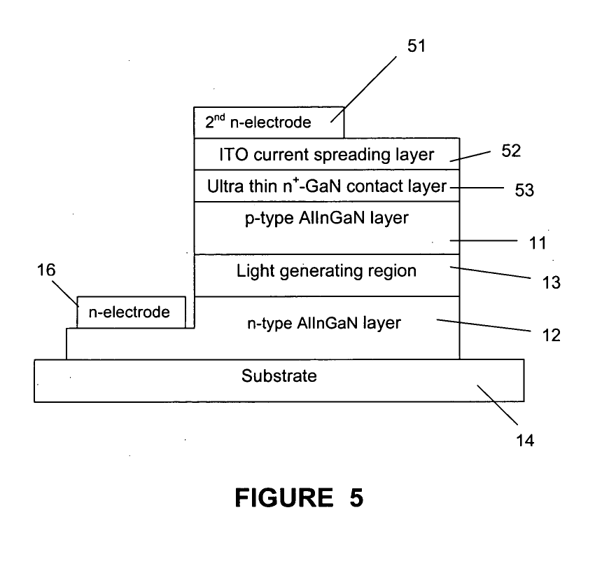

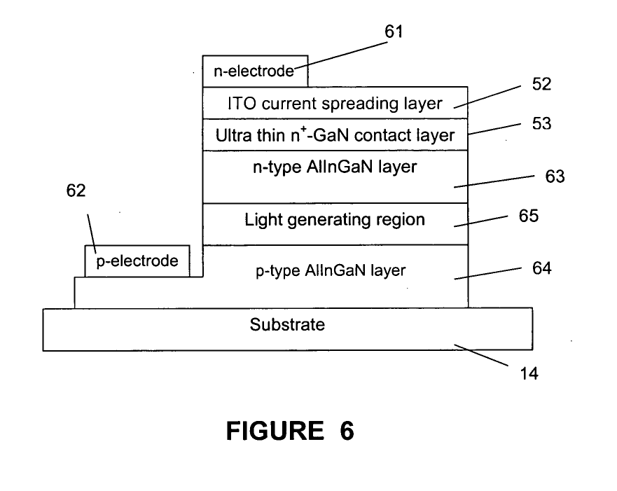

The present invention is illustrated in FIGS. 5 and 6, which depict (presently preferred embodiments thereof, as discussed in detail below. FIGS. 1-4 depict prior art LEDs and are discussed in detail above.

The present invention provides an LED device design which provides enhanced light output efficiency and/or provides lower device fabrication costs. The LED design utilizes a transparent conductive layer for current spreading to enhance light output efficiency.

The transparent conductive material can be chosen from one of the conductive oxides such as ZnO based and Indium Tin oxide (ITO) based compounds. It should be appreciated that both ITO and zinc oxides makes good contact with n⁺-GaN. ZnO based compounds include but are not limited to ZnO, ZnGaO, ZnAlO, etc.

ITO based compounds include, but are not limited to InOₓ, ITO, SnOₓ, etc. There may be other types of material not mentioned here that are also suitable for the similar use. The transparent conductive layer is in ohmic contact with the top layer of the LED structure. Most of the conductive oxides form good ohmic contact with n⁺-type GaN. The sheet resistivity of the conductive oxide can be chosen in the range of 10-200 ohm/sq, depending on the size of the device. The larger the size of the device, the smaller the sheet resistivity of the oxide layer that is required and therefore the thicker the oxide layer.

Referring now to FIG. 5, one exemplary embodiment of the present invention is shown, wherein an p-side up Group III-nitride based LED device structure is utilized.

The p-side up device comprises a substrate 14 having an n-type AlInGaN layer 12 formed thereon. A p-type AlInGaN layer 11 is formed upon the n-type AlInGaN layer 12, so as to define a light generating region 13. An ultra thin n+ GaN contact layer 53 is formed upon the p-type AlInGaN layer 11 and a conductive oxide layer, such as ITO current spreading layer 52, is formed upon the n+ GaN contact layer 53. An n-electrode 16 facilitates electrical contact to the n-type AlInGaN layer 12 and a second n-electrode 51 similarly facilitates electrical contact to the p-type AlInGaN layer 11.

According to this exemplary embodiment, an n⁺-AlInGaN based contact layer 53 is used to form tunneling diode with the top p-type GaN based layer 11. A transparent conductive oxide layer 52 forms ohmic contact with the n⁺-AlInGaN 53.

The n⁺-AlInGaN layer 53 is preferably grown at relatively low temperatures (700-900° C.) and made very thin, on the order of 100 Å, so as to preserve material and surface quality. Smooth surface morphology is necessary to obtain a good ohmic contact with the transparent conductive oxide layer.

Referring now to FIG. 6, another exemplary embodiment of the present invention is shown, wherein an n-side up Group III-nitride based LED device structure is utilized.

The n-side up device comprises a substrate 14 having a p-type AlInGaN layer 64 formed thereon. An n-type AlInGaN layer 63 is formed upon the p-type AlInGaN layer 64, so as to define a light generating region 65. An ultra thin n+ GaN contact layer 53 is formed upon the n-type AlInGaN layer 63 and a conductive oxide layer, such as ITO current spreading layer 52, is formed upon the n+ GaN contact layer 53. A p-electrode 62 facilitates electrical contact to the p-type AlInGaN layer 64 and an n-electrode 61 similarly facilitates electrical contact to the n-type AlInGaN layer 63.

The n-side up device structure can be made by either direct growth or by wafer bonding a p-side up LED structure to a conductive substrate and then lifting-off the original substrate to expose the n-type layer. In order to form good ohmic contact to the transparent conductive oxide layer, the exposed n-layer is preferably heavily doped to >1E19 cm⁻³ carrier concentration.

Light is partially reflected when it encounters a boundary between media of different refractive index. In order to enhance light transmission, an index matching technique is often used. For example, for a given wavelength (λ), and two media with high and low refractive index (nₘ₁,nₘ₂), light transmission can be enhanced by inserting a matching layer of material in between with a refractive index in between the high and low value of the two media.

When the thickness (T) and the refractive index of the matching layer (n_{matching}) are chosen to satisfy the following equations, reflection is minimized and therefore the transmission is maximized.
T(nm)=0.25λnm/n_{matching}
n_{matching}²=nₘ₁ nₘ₂
R=(nₘ₁ nₘ₂−n_{matching}²)²/(nₘ₁ nₘ₂+n_{matching}²)²=0

Even when the refractive indices are not met in the equation above, the reflection can still be reduced by choosing n_{matching} in between nₘ₁ and nₘ₂. This technique can be applied to the inventions of FIG. 5 and FIG. 6 by choosing proper material and layer thickness.

One example is to use an ITO with thickness equal to T (nm)=0.25λnm/n_{matching}. Where n_{matching} is about 1.9 in visible wavelength range. For a typical InGaN LED emitting at 470 nm, the matching ITO thickness will be 61.8 nm. It is possible that at a thickness of only 61.8 nm current spreading could be a problem. This depends on the size of the device. For larger size device, it is necessary to use a thicker ITO layer. In this case, one can choose to use integer number of quarter wave thickness such as 2T, 3T, etc.

The advantages of the present invention includes providing a transparent conductive layer to enhance current spreading without degrading light output. The enhanced current spreading allows the design of a large size device for high flux applications. Optionally, one or more index matching layers may be used to even further enhance light output. Thus, the present invention provides enhanced light output intensity and/or lower production costs.

It is understood that the exemplary light emitting devices described herein and shown in the drawings represent only presently preferred embodiments of the invention. Indeed, various modifications and additions may be made to such embodiments without departing from the spirit and scope of the invention. Thus, these and other modifications and additions may be obvious to those skilled in the art and may be implemented to adapt the present invention for use in a variety of different applications.

1. A light emitting device comprising:
two differently doped semiconductor materials defining a light generating region;
at least one n+ layer formed upon at least one of the two semiconductor materials; and
a current spreading layer formed upon the n+ layer.

2. A light emitting device comprising:
an n-type layer;
a p-type layer cooperating with the n-type layer to form a light generating region;
at least one n+ layer formed upon at least one of the n-type layer and the p-type layer; and
at least one current spreading layer formed upon the n+ layer.

3. The light emitting device as recited in claim 2, further comprising a substrate upon which at least one of the n-type layer and the p-type layer are formed.

4. The light emitting device as recited in claim 2, wherein the n+ layer is formed upon the p-type layer and further comprising a substrate upon which the n-type layer is formed.

5. The light emitting device as recited in claim 2, wherein the n+ layer is formed upon the n-type layer and further comprising a substrate upon which the p-type layer is formed.

6. The light emitting device as recited in claim 2, wherein the n-type layer and the p-type layer comprise AlInGaN.

7. The light emitting device as recited in claim 2, wherein the n+ layer comprises GaN.

8. The light emitting device as recited in claim 2, wherein the current spreading layer comprises a conductive oxide layer.

9. The light emitting device as recited in claim 2, wherein the current spreading layer comprises an indium tin oxide layer.

10. The light emitting device as recited in claim 2, wherein the current spreading layer comprises a material selected from the group consisting of:
InO_{X},
Indium Tin Oxide; and
SnO_{X}.

11. The light emitting device as recited in claim 2, wherein the current spreading layer comprises a zinc oxide layer.

12. The light emitting device as recited in claim 2, wherein the current spreading layer comprises a material selected from the group consisting of:
ZnO;
ZnGaO; and
ZnAlO.

13. The light emitting device as recited in claim 2, wherein the current spreading layer and the n+ layer are substantially transparent to at least one wavelength of visible light.

14. The light emitting device as recited in claim 2, wherein the sheet resistivity of the current spreading layer is less than approximately 200 ohm/sq.

15. The light emitting device as recited in claim 2, wherein the sheet resistivity of the current spreading layer is between approximately 10 ohms/cm² and approximately 200 ohm/sq.

16. The light emitting device as recited in claim 2, wherein a thickness of the n+ layer is less than approximately 100 angstroms.

17. The light emitting device as recited in claim 2, wherein a doping concentration of the n+is greater than 10¹⁹ cm⁻³

18. The light emitting device as recited in claim 2, wherein the conductive oxide layer is in ohmic contact with at least one of the n-layer and an n⁺-layer.

19. The light emitting device as recited in claim 2, wherein the n+ layer cooperates with at least one of the n-type layer and the p-type layer to define a tunneling diode.

20. The light emitting device as recited in claim 2, wherein a thickness of the oxide layer is an integer number of T, where T is 0.25λnm/n_{oxide}, λ is the emitting wavelength of the light generated from the light emitting device, and n_{oxide} is the refractive index of the oxide material.

21. A method for forming a light emitting device, the method comprising:
forming a light generating region from two differently doped semiconductor materials;
forming at least one n+ layer upon at least one of the two semiconductor materials; and
forming a current spreading layer upon the n+ layer.

22. A method for forming a light emitting device, the method comprising:
forming an n-type layer and a p-type layer in a manner such that they cooperate with one another to define a light generating region;
forming at least one n+ layer upon at least one of the n-type layer and the p-type layer; and
forming at least one current spreading layer upon the n+ layer.

23. The method as recited in claim 22, wherein at least one of the n-type layer and the p-type layer are formed upon a substrate.

24. The method as recited in claim 22, wherein the n+ layer is formed upon the p-type layer and wherein the n-type layer is formed upon a substrate.

25. The method as recited in claim 22, wherein the n+ layer is formed upon the n-type layer and wherein the p-type layer is formed upon a substrate.

26. The method as recited in claim 22, wherein the n-type layer and the p-type layer comprise AlInGaN.

27. The method as recited in claim 22, wherein the n+ layer comprises GaN.

28. The method as recited in claim 22, wherein the current spreading layer comprises a conductive oxide layer.

29. The method as recited in claim 22, wherein the current spreading layer comprises an indium tin oxide layer.

30. The method as recited in claim 22, wherein the current spreading layer comprises a material selected from the group consisting of:
InO_{X},
Indium Tin Oxide; and
SnO_{X}.

31. The method as recited in claim 22, wherein the current spreading layer comprises a zinc oxide layer.

32. The method as recited in claim 22, wherein the current spreading layer comprises a material selected from the group consisting of:
ZnO;
ZnGaO; and
ZnAlO.

33. The method as recited in claim 22, wherein the current spreading layer and the n+ layer are substantially transparent to at least one wavelength of visible light.

34. The method as recited in claim 22, wherein the sheet resistivity of the current spreading layer is less than approximately 200 ohm/sq.

35. The method as recited in claim 22, wherein the sheet resistivity of the current spreading layer is between approximately 10 ohms/cm² and approximately 200 ohm/sq.

36. The method as recited in claim 22, wherein a thickness of the n+ layer is less than approximately 100 angstroms.

37. The method as recited in claim 22, wherein a doping concentration of the n+is greater than 10¹⁹ cm⁻³

38. The method as recited in claim 22, wherein the conductive oxide layer is in ohmic contact with the n-layer.

39. The method as recited in claim 22, wherein the n+ layer cooperates with at least one of the n-type layer and the p-type layer to define a tunneling diode.

40. The method as recited in claim 22, wherein a thickness of the oxide layer is an integer number of T, where T is 0.25λnm/n_{oxide}, λ is the emitting wavelength of the light generated from the light emitting device, and n_{oxide} is the refractive index of the oxide material.

41. The method as recited in claim 22, wherein the n+ layer is formed at a temperature of less than approximately 900° C.

42. The method as recited in claim 22, wherein the n+ layer is formed at a temperature of between approximately 700° C. and approximately 900° C.
